(19) United States
(12) Patent Application Publication
(10) Pub. No.: US 2025/0372466 A1
(43) Pub. Date: Dec. 4, 2025

(54) PACKAGE CIRCUIT INCLUDING HOMOGENEOUS DIES

(71) Applicant: SAMSUNG ELECTRONICS CO., LTD, Suwon-si (KR)

(72) Inventors: Dongsu LEE, Suwon-si (KR); Sangsoon Im, Suwon-si (KR)

(73) Assignee: SAMSUNG ELECTRONICS CO., LTD., Suwon-si (KR)

(21) Appl. No.: 19/095,836

(22) Filed: Mar. 31, 2025

(30) Foreign Application Priority Data
May 31, 2024 (KR) 10-2024-0071821
Jul. 30, 2024 (KR) 10-2024-0101125

(51) Int. Cl. H01L 21/66; G01R 31/3177; G01R 31/3185

(52) U.S. Cl. CPC H01L 22/34; G01R 31/3177; G01R 31/318513; G01R 31/318572

(57) ABSTRACT

Provided is a package circuit including a plurality of homogeneous dies including a plurality of input/output terminals, and a joint test action group (JTAG) interface configured to transfer test signals applied to at least one of the plurality of homogeneous dies, wherein a test mode of the plurality of homogeneous dies operates in at least one of a first mode configured to test in series at least two dies among the plurality of homogeneous dies, a second mode configured to test in parallel at least two or more dies among the plurality of homogeneous dies, and a third mode configured to test individually any one die among the plurality of homogeneous dies, and wherein the JTAG interface includes four or five signal terminals.

### CROSS-REFERENCE TO RELATED APPLICATION

This application is based on and claims priority to Korean Patent Application Nos. 10-2024-0071821, filed on May 31, 2024 and 10-2024-0101125, filed on Jul. 30, 2024, in the Korean Intellectual Property office, the disclosures of which are incorporated by reference herein in their entireties.

### BACKGROUND

The disclosure relates to a package circuit including homogeneous dies. More particularly, the disclosure relates to a structure for testing the package circuit including the homogeneous dies.

As semiconductor manufacturing processes have become more refined, it has become possible to configure integrated circuits (ICs) with various purposes on a single die, which has resulted in an improvement in the degree of integration inside the single die. The result means that tests on each individual IC built onto the single die need to be performed, and accordingly, there are issues of standardization for solving interoperability. Accordingly, test standards, such as IEEE 1149.1, 1687, and 1500, are presented. By providing standardized interfaces and data models by using the test standards, the efficiency of test and verification processes have been improved. However, because the number of connection balls implementable in a semiconductor package is limited by the area of the semiconductor package, allocating balls for tests only causes reduction in the number of balls available for basic operations other than the tests, and thus, may cause a decrease in chip performance. This possibility acts as an issue in the verification process in which various tests need to be performed.

### SUMMARY

Provided is a device capable of shortening a test time, by applying various test modes, without additional pins, on a package integrated circuit including a plurality of homogeneous dies.

According to an aspect of the disclosure, a package circuit includes: a plurality of homogeneous dies including a plurality of terminals; and a joint test action group (JTAG) interface configured to transfer test signals applied to at least one of the plurality of homogeneous dies, wherein a test mode of the plurality of homogeneous dies incudes at least one of: a first mode configured to test in series at least two dies among the plurality of homogeneous dies; a second mode configured to test in parallel at least two dies among the plurality of homogeneous dies; and a third mode configured to test individually any one die among the plurality of homogeneous dies, and wherein the JTAG interface includes four or five signal terminals.

According to an aspect of the disclosure, a package circuit includes: a first die including a plurality of first terminals; a second die including a plurality of second terminals; and a joint test action group (JTAG) interface configured to transfer test signals applied to at least one of the first die or the second die, wherein the first die and the second die include homogeneous dies, wherein a number of terminals included in the JTAG interface is four or five, and wherein the plurality of first terminals and the plurality of second terminals each includes: signal terminals corresponding to the terminals included in the JTAG interface; and a first signal terminal configured to receive identification (ID) information of a die for distinguishing the first die from the second die.

According to an aspect of the disclosure, a package circuit includes: a plurality of homogeneous dies including a plurality of terminals; and a joint test action group (JTAG) interface configured to transfer test signals applied to at least one of the plurality of homogeneous dies, wherein the JTAG interface includes a test clock (TCK) signal terminal, a test mode select (TMS) signal terminal, a test reset (TRST) signal terminal, a test data input (TDI) signal terminal, and a test data output (TDO) signal terminal, and wherein each of the plurality of homogeneous dies includes: signal terminals respectively corresponding to the TCK signal terminal, the TMS signal terminal, the TRST signal terminal, the TDI signal terminal, and the TDO signal terminal; and standard input (STDI) signal terminals and standard output (STDO) signal terminals configured to transfer input signals and output signals between the plurality of homogeneous dies.

### BRIEF DESCRIPTION OF DRAWINGS

The above and other aspects and features of certain embodiments of the present disclosure will be more apparent from the following description taken in conjunction with the accompanying drawings, in which:

FIG. 1A is a block diagram of a package circuit according to one or more embodiments;

FIG. 1B is a block diagram of a die and a joint test action group (JTAG) interface, according to one or more embodiments;

FIGS. 2A and 2B are block diagrams of package circuits according to comparative embodiments;

FIG. 3 is a block diagram of a package circuit according to one or more embodiments;

FIG. 4A is a block diagram for describing components of a die and signals which are input/output to/from the components, according to one or more embodiments;

FIG. 4B is a detailed block diagram of signals which are input/output to/from a die, according to one or more embodiments;

FIG. 5 is a block diagram of components of a test access point (TAP) multiplexer (MUX) circuit according to one or more embodiments;

FIG. 6A illustrates a logic circuit of an example of a logic selection circuit and a master/slave selection circuit of a TAP MUX circuit;

FIG. 6B is a logic circuit of an example of an input selection circuit of a TAP MUX circuit;

FIG. 6C is a logic circuit of an example of an output selection circuit of a TAP MUX circuit;

FIG. 7 illustrates a logic circuit of a TAP MUX circuit, according to one or more embodiments;

FIG. 8 is a diagram to describe a method of selecting a master die and a slave die, according to one or more embodiments;

FIGS. 9A, 9B, 9C, 9D and 9E are diagrams of embodiments of selecting input signals and output signals in a test mode of a die; and

FIG. 10 is a flowchart of a test method of a package circuit, according to one or more embodiments.

### DETAILED DESCRIPTION

Hereinafter, one or more embodiments of the disclosure are described in conjunction with the accompanying drawings. In the following description, like reference numerals refer to like elements throughout the specification.

Terms such as “unit”, “module”, “member”, and “block” may be embodied as hardware or software. As used herein, a plurality of “units”, “modules”, “members”, and “blocks” may be implemented as a single component, or a single “unit”, “module”, “member”, and “block” may include a plurality of components.

It will be understood that when an element is referred to as being “connected” with or to another element, it can be directly or indirectly connected to the other element, wherein the indirect connection includes “connection via a wireless communication network”.

Also, when a part “includes” or “comprises” an element, unless there is a particular description contrary thereto, the part may further include other elements, not excluding the other elements.

Throughout the description, when a member is “on” another member, this includes not only when the member is in contact with the other member, but also when there is another member between the two members.

As used herein, the expressions “at least one of a, b or c” and “at least one of a, b and c” indicate “only a,” “only b,” “only c,” “both a and b,” “both a and c,” “both b and c,” and “all of a, b, and c.”

It will be understood that, although the terms “first”, “second”, “third”, etc., may be used herein to describe various elements, is the disclosure should not be limited by these terms. These terms are only used to distinguish one element from another element.

As used herein, the singular forms “a,” “an” and “the” are intended to include the plural forms as well, unless the context clearly indicates otherwise.

With regard to any method or process described herein, an identification code may be used for the convenience of the description but is not intended to illustrate the order of each step or operation. Each step or operation may be implemented in an order different from the illustrated order unless the context clearly indicates otherwise. One or more steps or operations may be omitted unless the context of the disclosure clearly indicates otherwise.

The various actions, acts, blocks, steps, or the like in the flow diagrams may be performed in the order presented, in a different order, or simultaneously. Further, in one or more embodiments, some of the actions, acts, blocks, steps, or the like may be omitted, added, modified, skipped, or the like without departing from the scope of the disclosure.

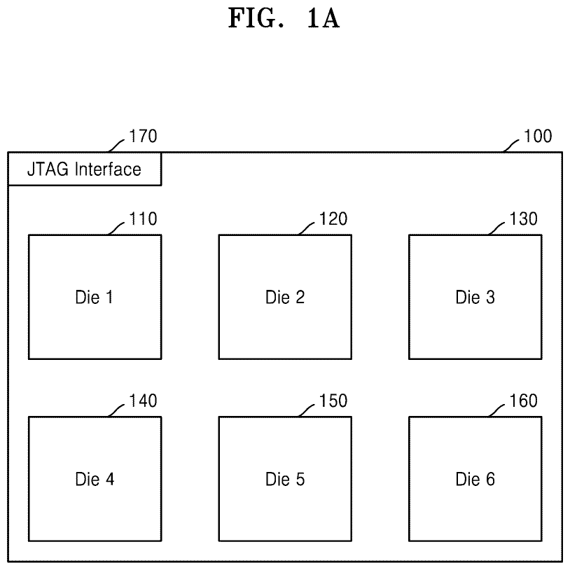

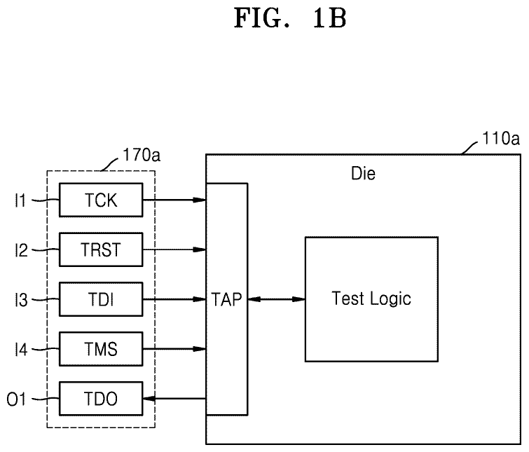

FIG. 1A is a block diagram of a package circuit 100 according to one or more embodiments.

Referring to FIG. 1A, the package circuit 100 may include a plurality of dies 110, 120, 130, 140, 150, and 160, or 110 through 160, and a joint test action group (JTAG) interface 170. According to one or more embodiments, the package circuit 100 may include an integrated circuit (IC). Hereinafter, the package circuit and the IC may be described interchangeably. According to one or more embodiments, the plurality of dies 110 through 160 may include on-chip logics to be tested. According to one or more embodiments, each of the plurality of dies 110 through 160 may include a plurality of signal terminals, and the plurality of signal terminals may include signal terminals corresponding to standard 5-pins included in the JTAG interface 170. In the disclosure, the terms “pins”, “signal terminals”, or “terminals” may be used interchangeably.

According to one or more embodiments, all of the plurality of dies 110 through 160 may include homogeneous dies. The expression “homogeneous dies” may mean dies including the same circuits or the same components. According to another embodiment, the expression “homogeneous dies” may mean dies that perform the same functions and output the same outputs when a certain input is input to the homogeneous dies, but where the internal components may not necessarily be the same.

According to one or more embodiments, the package circuit 100 according to the disclosure may include a plurality of homogeneous dies 110 through 160, and the plurality of homogeneous dies 110 through 160 may be tested in various modes by using the JTAG interface 170 that follows the IEEE 1149.1 standard.

According to one or more embodiments, the package circuit 100 according to the disclosure may include a package circuit of dies intended for a high speed computing (HPC) and an artificial intelligence (AI) accelerator. According to one or more embodiments, the package circuit 100 according to the disclosure may include a multi-die package circuit including a plurality of homogeneous dies such as a buffer die of a high bandwidth memory (HBM). According to one or more embodiments, because a large number of microbumps used in mission operations is required by dies requiring high performance, such as dies intended for the HPC and the AI accelerator, the number of test pads included in a single die may be limited. In the disclosure, a package circuit capable of improving this limit is proposed.

FIG. 1B is a block diagram of a die 110a and a JTAG interface 170a, according to one or more embodiments.

The die 110a illustrated in FIG. 1B may correspond to the die 110 illustrated in FIG. 1A. Referring to FIG. 1B, the die 110a may include five terminals for interfacing with a JTAG interface 170a external thereto. For example, to be connected to the JTAG interface 170a, the die 110a may include terminals corresponding to a terminal test mode select (TMS) I4 receiving a test mode selection signal, a terminal test clock (TCK) I1 receiving a test clock signal, a terminal test data output (TDO) O1 outputting test data, a terminal test data input (TDI) I3 receiving test data, and a terminal test reset (TRST) I2 resetting test data. According to one or more embodiments, the TRST I2 for resetting test data may be selectively provided. According to one or more embodiments, the IEEE 1149.1 standard may be referred to, for terminals included in the JTAG interface 170a and signals input/output via each of the terminals.

The IEEE 1149.1 standard may provide an abstraction layer of a high level for access and control of instrumentation devices embedded in a semiconductor device. Referring to FIG. 1B, the JTAG interface 170a may set an internal test circuit of the die 110a or output a value of the internal test circuit via a test access point TAP. In this manner, accessibility to a logic circuit to be tested may be secured, and efficient test and measurement may be feasible.

According to one or more embodiments, output data and input data may be transmitted and input, that is, via the TDO O1 through which test data is output and the terminal TDI I3 through which test data is input, respectively, via the JTAG interface 170a external to the die 110a.

According to the disclosure, in a multi-chip-module package chip including the homogeneous dies, all dies may share one JTAG interface to perform testing. To this end, by using terminals or interfaces used to distinguish the identifications (IDs) of the homogeneous dies in the package circuit, the master/slave status of individual dies may be determined, and by configuring a device for determining input/output directions of a JTAG signal in the die in which the master/slave status thereof is determined, it may be possible to configure a test environment of a shared JTAG signal for the same dies according to the status of the dies.

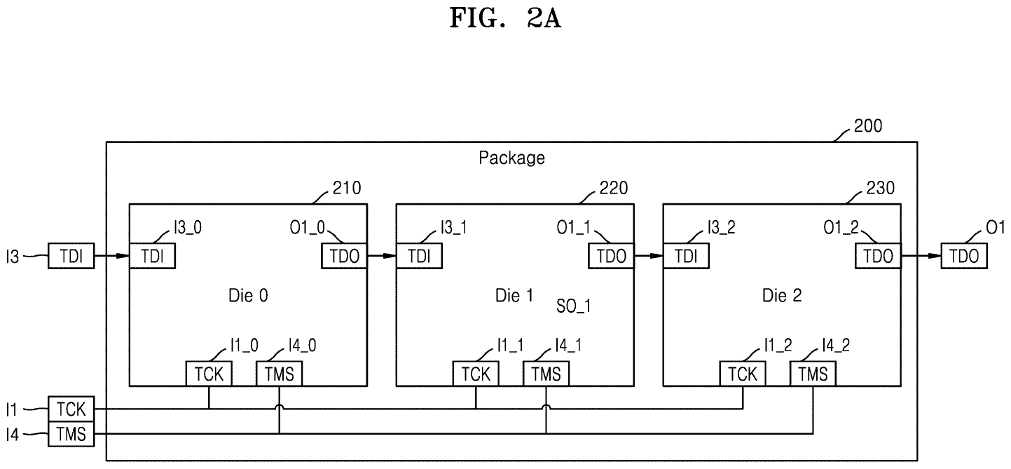

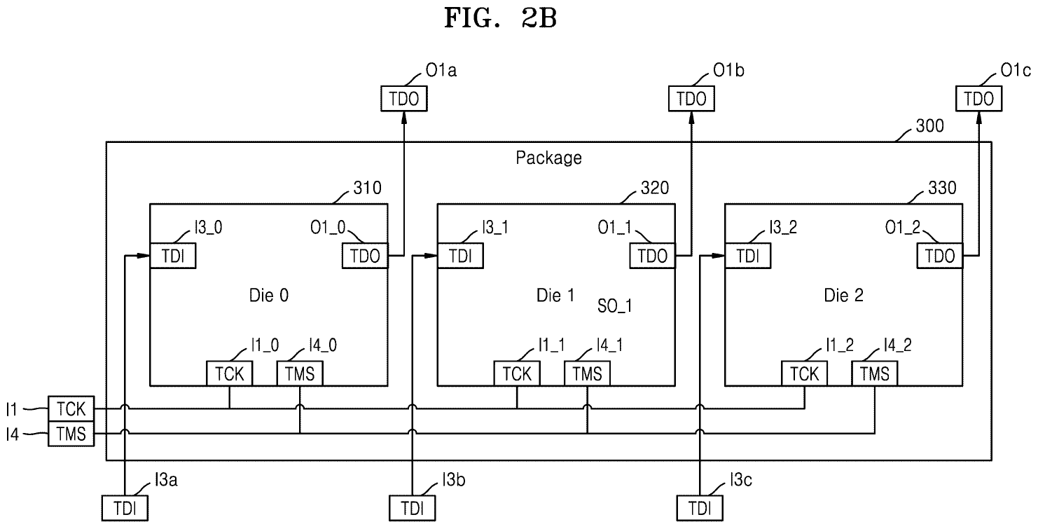

FIGS. 2A and 2B are block diagrams of package circuits 200 and 300 according to comparative embodiments, respectively.

Referring to FIG. 2A, the package circuit 200 may include a first die 210, a second die 220, and a third die 230. The first die 210, the second die 220, and the third die 230 may include homogeneous dies. To test the first die 210, the second die 220, and the third die 230 included in the package circuit 200, the JTAG interface may be connected to the package circuit 200. The JTAG interface may include a TCK signal terminal I1 for receiving a signal transmitted to the package circuit 200, a TMS signal terminal I4, a TDI signal terminal I3, and a TDO signal terminal O1 for outputting a signal sent from the package circuit 200. For convenience of description, a TRST signal is omitted in FIG. 2A. In the disclosure, a “signal” may mean a digital signal including 1 or more bits, or may also be referred to as data.

Referring to FIG. 2A, the first die 210 may include a TCK signal terminal I1_0, a TMS signal terminal I4_0, a TDI signal terminal I3_0, and a TDO signal terminal O1_0. The second die 220 may include a TCK signal terminal I1_1, a TMS signal terminal I4_1, a TDI signal terminal I3_1, and a TDO signal terminal O1_1. The third die 230 may include a TCK signal terminal I1_2, a TMS signal terminal I4_2, a TDI signal terminal I3_2, and a TDO signal terminal O1_2.

Referring to FIG. 2A, the TDO signal terminal O1_0 of the first die 210 may be connected to the TDI signal terminal I3_1 of the second die 220, and the TDO signal terminal O1_1 of the second die 220 may be connected to the TDI signal terminal I3_2 of the third die 230.

The TDI signal terminal I3 included in the JTAG interface may be connected to the TDI signal terminal I3_0 of the first die 210, and the TDO signal terminal O1 included in the JTAG interface may be connected to the TDO signal terminal O1_2 of the third die 230.

A plurality of dies, that is, the first, second, and third dies 210, 220, and 230 according to the embodiment of FIG. 2A, may be configured in a daisy-chain form. In the case of configuring in the daisy-chain form, because a test is required to be performed once for each of the same dies, an increase in the test time may occur.

Referring to FIG. 2B, the package circuit 300 may include a first die 310, a second die 320, and a third die 330. The first die 310, the second die 320, and the third die 330 may include homogeneous dies. To test the first die 310, the second die 320, and the third die 330 included in the package circuit 300, the JTAG interface may be connected to the package circuit 300. The JTAG interface may include the TCK signal terminal I1 for receiving a signal transmitted to the package circuit 300, the TMS signal terminal I4, the TDI signal terminal I3, and the TDO signal terminal O1 for outputting a signal from the package circuit 300. For convenience of description, the TRST signal is omitted in FIG. 2B.

Referring to FIG. 2B, the first die 310 may include the TCK signal terminal I1_0, the TMS signal terminal I4_0, the TDI signal terminal I3_0, and the TDO signal terminal O1_0. The second die 320 may include the TCK signal terminal I1_1, the TMS signal terminal I4_1, the TDI signal terminal I3_1, and the TDO signal terminal O1_1. The third die 330 may include the TCK signal terminal I1_2, the TMS signal terminal I4_2, the TDI signal terminal I3_2, and the TDO signal terminal O1_2.

Referring to FIG. 2B, each of the first, second, and third dies 310, 320, and 330 may share the TCK signal terminal I1 and the TMS signal terminal I4 among the terminals constituting the JTAG interface. Referring to FIG. 2B, the TDI signal terminals I3a, 13b, and 13c of the JTAG interface, to which signals are received from the outside, may be provided separately to be connected to the TDI signal terminals I3_0, I3_1, and I3_2 of the first, second, and third dies 310, 320, and 330, respectively, and the TDO signal terminals O1a, O1b, and O1c may be provided separately to be connected to the TDO signal terminals O1_0, O1_1, and O1_2 of the first, second, and third dies 310, 320, and 330, respectively.

Accordingly, when a plurality of dies share TCK signal terminals, TMS signal terminals, and TRST signal terminals among five terminals constituting the JTAG interface as illustrated in FIG. 2B, because a TDI signal terminal and a TDO signal terminal are required for each die, in the case when a package circuit includes N dies, at least 2N+3 signal terminals may be required, and thus, when the number of dies are multiple, there is an issue that the number of signal terminals for test is excessive. In this case, N may be a natural number equal to or greater than 2.

According to comparative embodiments, the number of package balls independently accessing each die may be limited in a chip where homogeneous dies are arranged in a single package circuit; and when a limited package size is considered, power and functional signals may be primarily allocated, and the number of balls for tests may be significantly limited. According to one or more embodiments, when 5 pins used in the JTAG interface are allocated as test balls of a plurality of homogeneous dies, and the plurality of homogeneous dies are configured as one package, 5n balls may be required, but this requirement may practically cause a difficult issue.

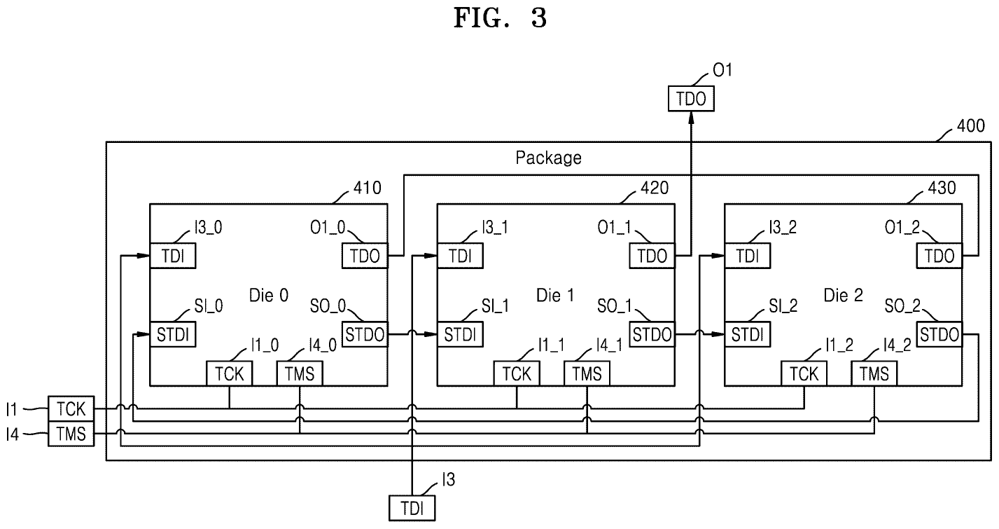

FIG. 3 is a block diagram of a package circuit 400 according to one or more embodiments.

Referring to FIG. 3, the package circuit 400 may include a first die 410, a second die 420, and a third die 430. The first die 410, the second die 420, and the third die 430 may include homogeneous dies. To test the first die 410, the second die 420, and the third die 430 included in the package circuit 400, the JTAG interface may be connected to the package circuit 400. The JTAG interface may include the TCK signal terminal Il for receiving signals transmitted to the package circuit 400, the TMS signal terminal I4, the TDI signal terminal I3, and the TDO signal terminal O1 for outputting signals from the package circuit 400. For convenience of description, the TRST signal is omitted in FIG. 3.

Referring to FIG. 3, the first die 410 may include the TCK signal terminal I1_0, the TMS signal terminal I4_0, the TDI signal terminal I3_0, a standard input (STDI) signal terminal SI_0, the TDO signal terminal O1_0, and a standard output (STDO) signal terminal SO_0. The second die 420 may include the TCK signal terminal I1_1, the TMS signal terminal I4_1, the TDI signal terminal I3_1, an STDI signal terminal SI_1, the TDO signal terminal O1_1, and an STDO signal terminal SO_1. The third die 430 may include the TCK signal terminal I1_2, the TMS signal terminal I4_2, the TDI signal terminal I3_2, an STDI signal terminal SI_2, the TDO signal terminal O1_2, and an STDO signal terminal SO_2. The STDI may include a serial TDI, and the STDO may include a serial TDO. In other words, an STDI signal terminal and an STDO signal terminal may include input/output terminals provided to individual dies for a serial test mode to be described below.

Referring to FIG. 3, the JTAG interface may use five signal terminals of the IEEE 1149.1 standard, and each of the dies may further include STDI signal terminals SI_0, SI_1, and SI_2 and STDO signal terminals SO_0, SO_1, and SO_2 capable of communicating between a plurality of homogeneous dies 410, 420, and 430. The signal terminals input from the outside of the package circuit 400 may include five signal terminals of the IEEE 1149.1 standard, and signal terminals for signals exchanged between the plurality of homogeneous dies, that is, the first, second, and third dies 410, 420, and 430, in the package circuit 400 may be further included. In this manner, there is an advantage in that an arrangement of an additional external testing terminal is not required based on the package circuit 400. According to one or more embodiments, in a single die package, the arrangement of additional test pins may be indispensable, but according to the disclosure, this indispensability may be overcome without arranging additional test pins.

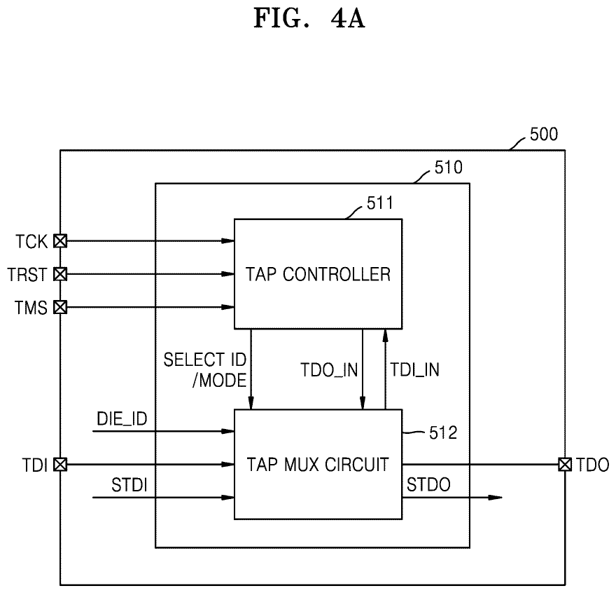

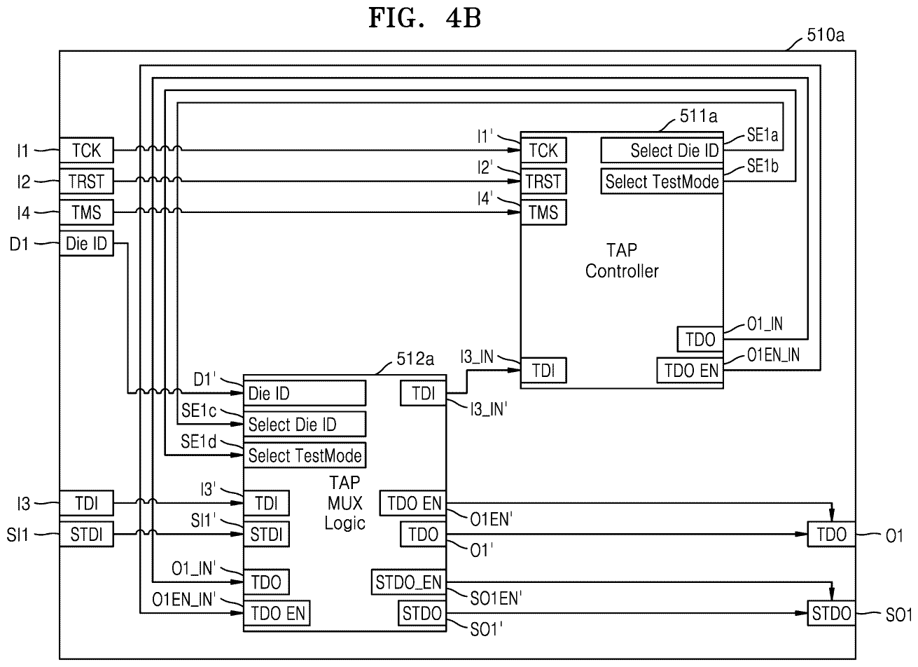

FIG. 4A is a block diagram illustrating components of a die 510 and signals which are input/output to/from the components of said die, according to one or more embodiments. Referring to FIG. 4A, an example of a package circuit 500 and a die 510 included in the package circuit 500 are illustrated. The package circuit 500 illustrated in FIG. 4A may include an example corresponding to any one of the package circuits 100 and 400 respectively illustrated in FIG. 1A and FIG. 3, and the die 510 illustrated in FIG. 4A may include an example corresponding to any one of the dies 110 through 160 and the first, second, and third dies 410, 420, and 430 respectively illustrated in FIG. 1A and FIG. 3.

In the present disclosure, signals input from or output to the outside of the package circuit may be referred to as external signals, and signals input or output between dies in the package circuit or signals input from other components in the package circuit may be referred to as internal signals. As used in the disclosure, the meaning of a signal terminal may be referred to as a node or a pin which receives or outputs a signal that is input to or output from a corresponding signal terminal. In the illustration of FIG. 4A, for convenience of explanation, flows of signals are shown with arrows, and the signal may be output from the start point of the arrow, and may be input to the arrival point of the arrow. In addition, for convenience of explanation, the terminals to which signals are input to, and from which the signals are output, are omitted in a test point port TAP controller 511 and a TAP MUX circuit 512, which is to be explained in more detail with reference to FIG. 4B.

An external signal received by or output from the package circuit 500 may include a signal according to the JTAG interface. According to one or more embodiments, an external signal of the package circuit 500 may include a TCK signal TCK, a TRST signal TRST, a TMS signal TMS, a TDI signal TDI, and a TDO signal TDO.

Referring to FIG. 4A, the die 510 may include the TAP controller 511 and the TAP MUX circuit 512. The TAP controller 511 may receive the TCK signal TCK, the TRST signal TRST, and the TMS signal TMS among the external signals. The TAP controller 511 may include signal terminals capable of receiving the TCK signal TCK, the TRST signal TRST, and the TMS signal TMS among the external signals. The TAP controller 511 may transmit a first selection signal SELECT ID/MODE to the TAP MUX circuit 512. According to one or more embodiments, the first selection signal SELECT ID/MODE may include information for determining a test mode of the die 510 included in the package circuit 500. According to one or more embodiments, the first selection signal SELECT ID/MODE may include identification ID information that may distinguish the die 510 included in the package circuit 500 from other dies included in the package circuit 500.

According to one or more embodiments, the TAP controller 511 may control the operation of the die to be tested by using the TDO signal TDO, the TCK signal TCK, the TDI signal TDI, the TMS signal TMS, and the TRST signal TRST. The TAP controller 511 according to one or more embodiments may also further include a register capable of storing necessary data in advance.

The TAP MUX circuit 512 may receive a second selection signal DIE_ID. According to one or more embodiments, the second selection signal DIE_ID may be generated by another component inside the package circuit 500 and input to the tap MUX circuit 512. The second selection signal DIE_ID may include ID information for distinguishing the corresponding die 510 from other dies. According to one or more embodiments, the second selection signal DIE_ID may include ID information of a hard-coded die.

The TAP MUX circuit 512 may compare the first selection signal SELECT ID/MODE to the second selection signal DIE_ID. According to one or more embodiments, the TAP MUX circuit 512 may compare the ID information of the hard-coded die to ID the die's information input by using the JTAG interface, and may determine whether the corresponding die is a master or a slave, whether the corresponding die is selected to be tested, and the test mode of the corresponding die.

The STDI signal STDI and/or the TDI signal TDI may be input to the TAP MUX circuit 512. According to one or more embodiments, the TAP MUX circuit 512 may determine one of the STDI signal STDI and the TDI signal TDI as an input signal. A determined internal input signal TDI_IN may be transmitted to the TAP controller 511, and may be determined as an input signal of the corresponding die 510. An internal output signal TDO_IN of the corresponding die 510 may be determined based on the determined internal input signal TDI_IN, and the determined internal output signal TDO_IN may be transmitted to the TAP MUX circuit 512.

The TAP MUX circuit 512 may output an STDO signal STDO and/or the TDO signal TDO. According to one or more embodiments, the TAP MUX circuit 512 may output the internal output signal TDO_IN output from the TAP controller 511 as the STDO signal STDO that transmits the internal output signal TDO_IN to another homogeneous die, or as the TDO signal TDO that is an external signal.

According to the embodiment of FIG. 4A, the JTAG interface may include the TCK signal TCK, the TRST signal TRST, the TDI signal TDI, the TDO signal TDO, and the TMS signal TMS according to the IEEE 1149.1 standard, but may additionally include the STDI signal STDI and the STDO signal STDO capable of transmitting signals internally. The operation of the JTAG interface may be performed by the tap controller 511, and the operation of the tap controller 511 may comply with the IEEE 1149.1 standard. According to one or more embodiments, the TAP MUX circuit 512 may determine the input/output direction of the test data at a die level by receiving the first selection signal SELECT ID/MODE output by the tap controller 511. According to one or more embodiments, the first selection signal SELECT ID/MODE may include a signal including both a signal for selecting the test mode and a signal related to die ID information. According to one or more embodiments of the disclosure, the test mode may include a parallel test mode, the serial test mode, and a single test mode. According to one or more embodiments, the TAP MUX circuit 512 may receive a hard-coded die ID as the second selection signal DIE_ID to determine whether an individual die is a master or a slave. In this manner, the disclosure may, in the package circuit including multiple homogeneous dies, distinguish a plurality of dies configured in a package circuit by utilizing a basic JTAG interface, perform tests on the plurality of dies, reduce the test time, and improve productivity.

FIG. 4B is a detailed block diagram of signals which are input/output to/from a die 510a, according to one or more embodiments.

Referring to FIG. 4B, a TAP controller 511a and a TAP MUX circuit 512a included in the die 510a are disclosed. The die 510a illustrated in FIG. 4B may be an example of the die 510 illustrated in FIG. 4A.

In the die 510a illustrated in FIG. 4B, terminals, via which signals are input/output to/from the TAP controller 511a and the TAP MUX circuit 512a, are illustrated. According to one or more embodiments, a plurality of terminals (I1, I2, I3, I4, O1, SI1, SO1, and D1) connected to the edge of the die 510a may receive and transmit signals applied from the outside of the die 510a. According to one or more embodiments, the TCK signal terminal I1, the TRST signal terminal I2, the TMS signal terminal I4, the TDI signal terminal I3, and the TDO signal terminal O1, among the terminals connected to the edge of the die 510a, may include signals input and output via the JTAG interface of a package circuit including the die 510a, and an STDI signal terminal SI1, an STDO signal terminal SO1, and a DIE_ID terminal D1, among the terminals connected to the edge of the die 510a, may include signals input and output in the inside of the package circuit including the die 510a.

The TAP controller 511a may include a TCK signal terminal I1′, a TRST signal terminal I2′, and a TMS signal terminal I4′ for receiving signals applied via the JTAG interface of a package circuit including the die 510a. The TAP controller 511a may include first selection signal terminals SE1a and SE1b for transmitting signals to the TAP MUX circuit 512a. According to one or more embodiments, the first selection signal terminals SE1a and SE1b may include terminals for transmitting the first selection signal SELECT ID/MODE in FIG. 4A. The first selection signal terminals SE1a and SE1b may include the first selection signal terminal SE1a including the SELECT DIE ID information to transmit the die ID information, and the first selection signal terminal SE1b including the TESTMODE information to select the test mode. The TAP controller 511a may include an internal TDI terminal I3_IN, an internal TDO terminal O1_IN, and an internal TDO EN terminal O1EN_IN for transmitting input signals and output signals between the TAP controller 511a and the TAP MUX circuit 512a. According to one or more embodiments, the internal TDI terminal I3_IN, the internal TDO terminal O1_IN, and the internal TDO EN terminal O1EN_IN may include terminals for transmitting the internal input signal TDI_IN and the internal output signal TDO_IN in FIG. 4A. According to one or more embodiments, the internal TDO EN terminal O1EN_IN may operate in conjunction with the internal TDO terminal O1_IN. According to one or more embodiments, the internal TDO EN terminal O1EN_IN may include an enable signal of the internal TDO terminal O1_IN.

The TAP MUX circuit 512a may include first selection signal terminals SE1c and SE1d corresponding to the first selection signal received from the TAP controller 511a. The first selection signal terminal SE1a of the TAP controller 511a may correspond to the first selection signal terminal SE1c of the TAP MUX circuit 512a, and the first selection signal terminal SE1b of the TAP controller 511a may correspond to the first selection signal terminal SE1d of the TAP MUX circuit 512a. According to one or more embodiments, a signal including information about a die ID may be input to the first selection signal terminal SE1c of the TAP MUX circuit 512a, and a signal including information about the test mode may be input to the first selection signal terminal SE1d of the tap MUX circuit 512a.

The TAP MUX circuit 512a may include a terminal D1′ for receiving the die ID information received from the outside of a die. According to one or more embodiments, the signal received via the terminal D1′ of the tap MUX circuit 512a may correspond to the second selection signal DIE_ID in FIG. 4A. According to one or more embodiments, the terminal D1′ for receiving the die ID information received from the outside of the die may include a second selection signal terminal.

The TAP MUX circuit 512a may include an internal TDI terminal I3_IN′ connected to the internal TDI terminal I3_IN of the TAP controller 511a, and may include an internal TDO terminal O1_IN′ and an internal TDO EN terminal O1EN_IN′ connected to the internal TDO terminal O1_IN of the TAP controller 511a.

The TAP MUX circuit 512a may include a TDI signal terminal I3′ connected to the TDI signal terminal I3 included in the JTAG interface, and may include an STDI signal terminal SI1′ connected to the STDI signal terminal SI1 applied from the outside of the die.

The TAP MUX circuit 512a may include a TDO signal terminal O1′ and a TDO EN signal terminal O1EN′ connected to the TDO signal terminal O1 included in the JTAG interface, and may include an STDO signal terminal SO1′ and an STDO EN signal terminal SO1EN′ connected to the STDO signal terminal SO1 in series with another die.

The TAP controller 511a and the TAP MUX circuit 512a according to the disclosure may perform tests by using the five pins (I1, I2, I3, I4, and O1) of the JTAG interface of the IEEE 1149.1 standard, and the STDI signal terminal and the STDO signal terminal which are additionally arranged. Inside an individual die, circuits capable of selecting test access paths by using an instruction register (IR) setting may be arranged, and in this manner, various access modes may be configured. According to the disclosure, additional logic for access to a die in the package circuit may not be required, and tests may be conducted by selecting a die to be accessed by using the 5 pins and a die identification register of the JTAG interface. According to one or more embodiments, the die 510a according to the disclosure may include JTAG interface terminals for simultaneously inputting signals into a master die or a slave die, and terminals to which signals are input to distinguish a plurality of homogeneous dies.

In other words, according to the disclosure, in a package IC for testing the homogeneous dies, there is no external input of output terminal to distinguish between the homogeneous dies, and by comparing an internal hard-coded die ID to an internal IR-set ID, the ID information of each die may be identified.

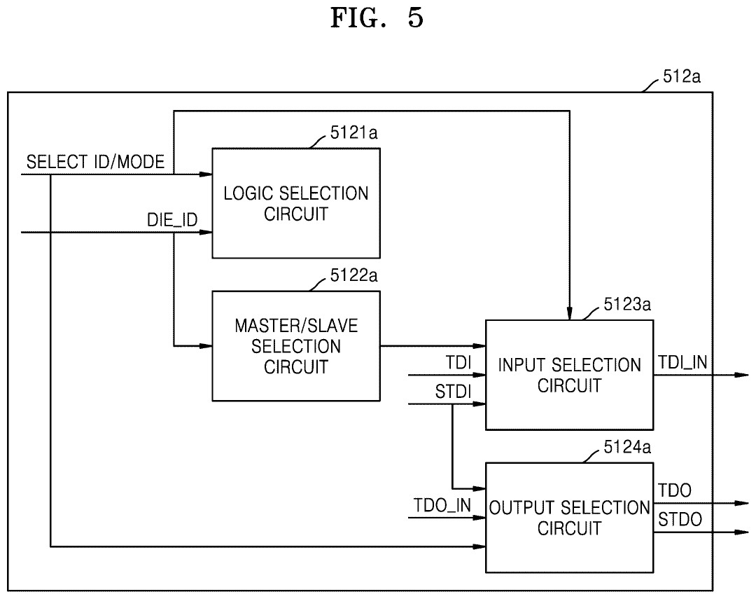

FIG. 5 is a block diagram of components of the TAP MUX circuit 512a according to one or more embodiments. The TAP MUX circuit 512a of FIG. 5 may correspond to the TAP MUX circuit 512 and 512a illustrated in FIGS. 4A and 4B.

The TAP MUX circuit 512a may include a logic selection circuit 5121a, a master/slave selection circuit 5122a, an input selection circuit 5123a, and an output selection circuit 5124a.

The first selection signal SELECT ID/MODE and the second selection signal DIE_ID may be input to the logic selection circuit 5121a. The logic selection circuit 5121a may compare the first selection signal SELECT ID/MODE to the second selection signal DIE_ID, and determine whether the corresponding die has been selected as a test target. According to one or more embodiments, when the first selection signal SELECT ID/MODE matches the second selection signal DIE_ID, it may be determined that the corresponding die has been selected as the test target, and when the first selection signal SELECT ID/MODE does not match the second selection signal DIE_ID, it may be determined that the corresponding die has not been selected as the test target.

The second selection signal DIE_ID may be input to the master/slave selection circuit 5122a. According to one or more embodiments, the second selection signal DIE_ID may be input as a plurality of bit signals. The master/slave selection circuit 5122a may determine whether the corresponding die is a master die or a slave die, by determining whether each of the plurality of bit signals satisfies a master/slave condition in which the second selection signal DIE_ID has been preset. The reason for determining whether a die is a master die or a slave die in the disclosure may be that in the serial test mode according to one or more embodiments, the master die is determined as the die which first receives the TDI signal input via the JTAG interface.

The TDI signal TDI, a STDI signal STDI, the first selection signal SELECT ID/MODE, and an output signal of the master/slave selection circuit 5122a may be input to the input selection circuit 5123a. According to one or more embodiments, the input selection circuit 5123a may determine which of the TDI signal TDI and the STDI signal STDI is selected as the input signal, based on the output signal of the master/slave selection circuit 5122a and the first selection signal SELECT ID/MODE, and may output the determined internal input signal TDI_IN.

An internal TDO signal TDO_IN, the STDI signal STDI, and the first selection signal SELECT ID/MODE may be input to the output selection circuit 5124a. The output selection circuit 5124a may determine whether to output the internal TDO signal TDO_IN as the TDO signal TDO or as the STDO signal STDO, based on the STDI signal STDI and the first selection signal SELECT ID/MODE.

Hereinafter, the operation method of each circuit is described in more detail by using one or more embodiments of the logic selection circuit 5121a, the master/slave selection circuit 5122a, the input selection circuit 5123a, and the output selection circuit 5124a.

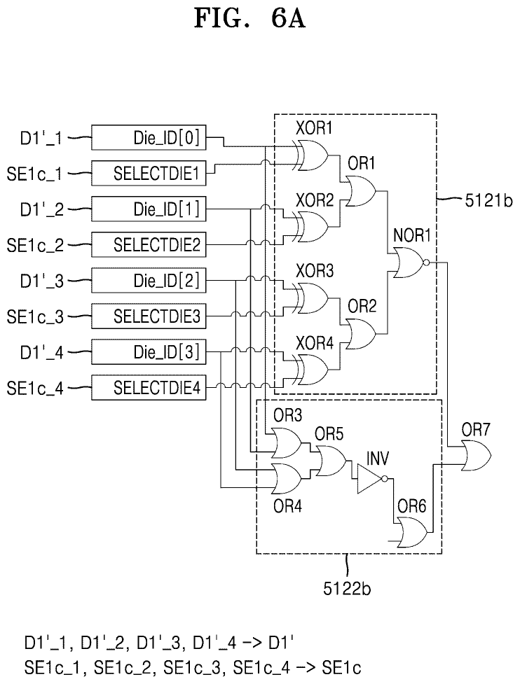

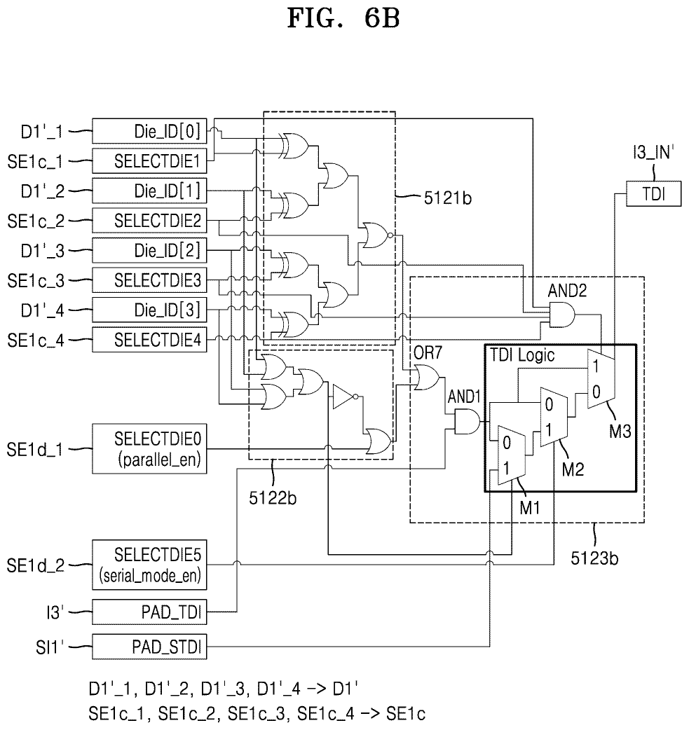

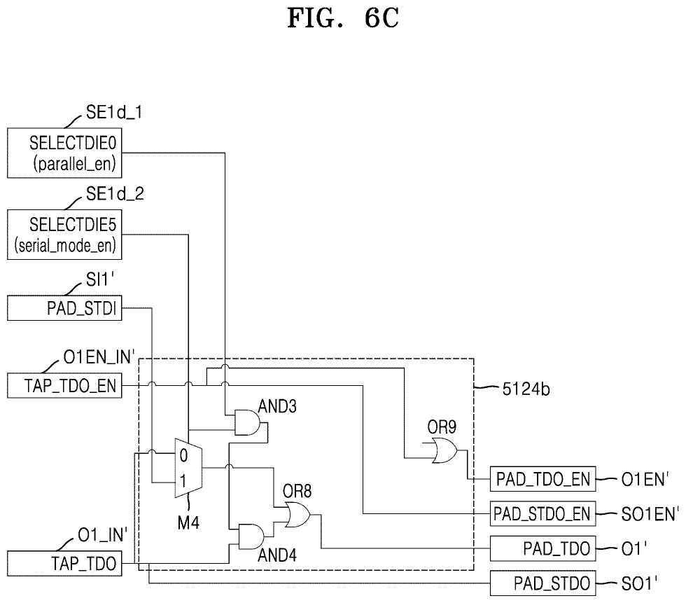

FIG. 6A illustrates a logic circuit illustrating an embodiment of a logic selection circuit 5121b and a master/slave selection circuit 5122b of a TAP MUX circuit.

Referring to FIG. 6A, an example of the logic selection circuit 5121b and the master/slave selection circuit 5122b is illustrated. The logic selection circuit 5121b and the master/slave selection circuit 5122b illustrated in FIG. 6A may correspond to the logic selection circuit 5121a and the master/slave selection circuit 5122a illustrated in FIG. 5, respectively.

Each of the logic selection circuit 5121b and the master/slave selection circuit 5122b may include a plurality of logic devices. The logic selection circuit 5121b may include four XOR gates, that is, first through fourth XOR gates XOR1 through XOR4, two OR gates OR1 and OR2, and one NOR gate NOR1. The signals SE1c_1, SE1c_2, SE1c_3, and SE1C_4 corresponding to each bit of the first selection signal terminal SE1c, and terminals D1′_1, D1′_2, D1′_3, and D1′_4 corresponding to each bit of the second selection signal terminal D1′ may be connect to the four XOR gates, that is, the first through fourth XOR gates XOR1 through XOR4, respectively. For example, the signal SE1c_1 corresponding to the first bit of the first selection signal terminal SE1c, and the signal D1′_1 corresponding to the first bit of the second selection signal terminal D1′ may be input to the first XOR gate XOR1. For example, the signal SE1c_2 corresponding to the second bit of the first selection signal terminal SE1c, and the signal D1′_2 corresponding to the second bit of the second selection signal terminal D1′ may be input to the second XOR gate XOR2. For example, the signal SE1c_3 corresponding to the third bit of the first selection signal terminal SE1c, and the signal D1′_3 corresponding to the third bit of the second selection signal terminal D1′ may be input to the third XOR gate XOR3. For example, the signal SE1c_4 corresponding to the fourth bit of the first selection signal terminal SE1c, and the signal D1′_4 corresponding to the fourth bit of the second selection signal terminal D1′ may be input to the fourth XOR gate XOR4. Each XOR gate may compare bits at each digit of signals input to the first selection signal terminal SE1c and the second selection signal terminal D1′, output 0 when the inputs are the same, and output 1 when the inputs are different. Accordingly, when the signal of the first selection signal terminal SE1c including the die ID information matches the signal of the second selection signal terminal D1′, the outputs of all XOR gates may be 0, and thus, the outputs of the OR gates OR1 and OR2, which receive outputs of all XOR gates, that is, the first through fourth XOR gates XOR1 through XOR4, as inputs, may also be 0. Finally, the output of the NOR gate NOR1 having the output of the OR gates OR1 and OR2 as an input may be 1. Thus, when the output of the NOR gate NOR1 is 1, it may mean that the signal of the first selection signal terminal SE1c including the die ID information matches the signal of the second selection signal terminal D1′. When the signal of the first selection signal terminal SE1c including the die ID information does not match the signal of the second selection signal terminal D1′, the output of the NOR gate NOR1 may be 0. In other words, by using a connection structure of the logic gates of the logic selection circuit 5121b, whether the signal of the first selection signal terminal SE1c including the die ID information matches the signal of the second selection signal terminal D1′ may be determined, and when the signal of the first selection signal terminal SE1c including the die ID information matches the signal of the second selection signal terminal D1′, it may be determined that the corresponding die is under test. According to one or more embodiments, only a selected die among the homogeneous dies may be tested by using the value of the first selection signal set by the TAP controller. According to one or more embodiments, the number of bits of the signal of the first selection signal terminal SE1c including the die ID information may be the same as the number of bits of the signal of the second selection signal terminal D1′.

The master/slave selection circuit 5122b may include four OR gates OR3, OR4, OR5, and OR6 and one inverter INV. According to one or more embodiments, the terminals D1′_1, D1′_2, D′_3, and D1′_4 corresponding to the second selection signal DIE_ID may be connected to the input terminal of the OR gates OR3 and OR4 of the master/slave selection circuit 5122b. In other words, bit signals of each digit number corresponding to the second selection signal DIE_ID may be applied as the input of the OR gates OR3 and OR4. According to one or more embodiments, it may be assumed that a condition for a die to be determined as a master die is set to “0000”. It may be assumed that a condition for a die to be determined as a slave die is other bit signals except for “0000”. Accordingly, when the bit signal of each digit corresponding to the second selection signal is “0000”, each of the outputs of the OR gates OR3 and OR4 may be 0, the output of the OR gate OR5 having the outputs of the OR gates OR3 and OR4 as an input of the OR gate OR5 may be 0, an output of the inverter INV connected to the output of the OR gate OR5 may be 1, and accordingly, the output of the OR gate OR6 may be 1. When the bit signal of each digit corresponding to the second selection signal is not “0000”, the output of any one of the OR gates OR3 and OR4 may be 1. Accordingly, the output of the OR gate OR5 may also be 1, the output of the inverter INV may be 0, and thus, the output of the OR gate OR6 may be 0 or 1. Although omitted in FIG. 6A, the signal input to the OR gate OR6 may include a signal for determining the parallel test mode. Because determining of the master/slave mode according to the disclosure is meaningful in the serial test mode, when a signal to be determined in the parallel test mode is applied as logic high, the output of the OR gate OR6 may be 1. In other words, when the output of the OR gate OR6 is 0, this case may mean a case of a slave die.

According to one or more embodiments, the master/slave selection circuit 5122b may determine whether a die is a master die or a slave die according to the value of the signal applied to the second selection signal DIE_ID. Inside the TAP MUX circuit, signals for selecting TDI signals, STDI signals, TDO signals, and STDO signals may be configured, and as a result, the test mode and a master/slave mode of each die may be selected to determine the input/output direction of the test data.

Although FIG. 6A of the disclosure illustrates that a signal applied to the first selection signal terminal SE1c including the die ID information and a signal applied to the second selection signal terminal D1′ are 4 bits each, a first selection signal SE1 may include both information about the die ID and information for determining the test mode. According to one or more embodiments, the terminal of the first selection signal SE1 may include a signal of a total of 6 bits, including the first selection signal terminal SE1c for receiving a 4-bit signal including information about the die ID and a terminal SE1d for receiving a 2-bit signal including information about the test mode. The terminal SE1d receiving a 2-bit signal including information about the test mode is described below with reference to FIG. 6B.

According to one or more embodiments, Die_IDs illustrated in FIG. 6A may include the ID information for distinguishing between a plurality of homogeneous dies in a package configuration. The Die_IDs may be a different ID for each die in a single package. According to one or more embodiments, to distinguish between the homogeneous dies within a single package circuit, the Die_IDs may be input to a die, and a master or slave may be set based on the Die_ID set in the single package.

FIG. 6B is a logic circuit of an example of an input selection circuit 5123b of a TAP MUX circuit.

In the description of FIG. 6B, duplicate configurations described with reference to FIG. 6A are omitted. Referring to FIG. 6B, the input selection circuit 5123b connected to the outputs of the logic selection circuit 5121b and the master/slave selection circuit 5122b is disclosed. The input selection circuit 5123b may include a plurality of logic devices. The input selection circuit 5123b may include an OR gate OR7, two AND gates AND1 and AND2, and three MUXs M1, M2, and M3. Referring to FIG. 6B, some bits, for example, SE1d_1 and SE1d_2, among 6-bit configurations of a first selection signal may be set as bit signals for a parallel test and a serial test.

The OR gate OR7 of the input selection circuit 5123b may receive the outputs of the logic selection circuit 5121b and the master/slave selection circuit 5122b as inputs. As described above, the OR gate OR7 may output a value of 0 when the corresponding die is in the test mode. The AND gate AND1 using the output of the OR gate OR7 and the output of the TDI signal terminal I3′ as inputs is disclosed, and the output of the corresponding AND gate AND1 may be connected to a first input to a first MUX M1 and a second MUX M2, or to a second input of a third MUX M3. The second input of the first MUX M1 may include the output of the STDI signal terminal SI1′, the second input of the second MUX M2 may include an output of the first MUX M1, and the first input of the third MUX M3 may include an output of the second MUX M2. Whether a die is determined as the master die in the master/slave selection circuit 5122b may be input as a control input of the first MUX M1, whether the test mode is determined as a serial test mode by connecting the first selection signal terminal SE1d may be used as the control input of the second MUX M2, and the output of an AND gate AND2 may be input as the control input of the third MUX M3. As the input of the AND gate AND2, signals corresponding to each bit of the first selection signals SE1c_1, SE1c_2, SE1c_3, and SE1c_4 may be input. According to one or more embodiments, when signals corresponding to each bit of the first selection signals SE1c_1, SE1c_2, SE1c_3, and SE1c_4 are 0000, the output of the AND gate AND2 may be 0.

According to one or more embodiments, the first MUX M1 may output the output of the AND gate AND1 when the first MUX M1 is a master die, but may output the STDI signal when the first MUX M1 is not a master die. According to one or more embodiments, the second MUX M2 may output the output of the AND gate AND1 when the test mode is not the serial test mode, and may output the output of the first MUX M1 when the test mode is the serial test mode. The third MUX M3 may output the output of the second MUX M2 when signals corresponding to each bit of the first selection signals SE1c_1, SE1c_2, SE1c_3, and SE1c_4 are not 1111, and may output the output of the AND gate AND1 when signals corresponding to each bit of the first selection signals SE1c_1, SE1c_2, SE1c_3, and SE1c_4 are 1111.

Accordingly, depending on whether the first selection signal, the test mode, or master/slave die is satisfied, whether the TDI signal is determined as an input signal or whether the STDI signal is determined as an input signal may be determined. The determined input signal may be output to the TAP controller via an internal TDI signal terminal I3_IN′. Referring to FIG. 6B, after the determination of the master/slave and selection of the die are completed by using the first selection signal and the second selection signal, it may be possible to determine which input signal is to be selected between an externally applied TDI signal TDI and the STDI signal STDI connected between dies by determining the test mode.

FIG. 6C is a logic circuit of an example of an output selection circuit 5124b of a TAP MUX circuit.

Referring to FIG. 6C, an example of the output selection circuit 5124b is illustrated. The output selection circuit 5124b may include a plurality of logic devices. The output selection circuit 5124b may include two AND gates AND3 and AND4, a MUX M4, and two OR gates OR8 and OR9. According to one or more embodiments, an input of the first selection signal terminal SE1d_2 for determining the serial test mode among the first selection signals may be input as a control input of the MUX M4, the internal TDO terminal O1_IN′ may be input as the first input, and an input of the STDI signal STDI terminal SI1′ may be input as the second input. In the serial test mode, the output of the MUX M4 may be the STDI signal, and in the non-serial test mode, the internal TDO signal may be output by the MUX M4. As the input of the AND gate AND3, the first selection signal terminal SE1d_2 for determining the serial test mode and a first selection signal terminal SE1d_1 for determining the parallel test mode among the first selection signals may be input. As an input of an AND gate AND4, the output of the AND gate AND3 and the output of the internal TDO terminal O1_IN′ may be input. The output of the MUX M4 and the output of the AND gate AND4 may be inputs of the OR gate OR8. Outputs of an internal TDO enable terminal O1EN_IN′ and the logic selection circuit 5121a may be inputs of the OR gate OR9.

According to one or more embodiments, an output direction of the internal TDO signal output from the TAP controller may be determined, according to the structure of the logic devices included in the output selection circuit 5124b. By using a structure of the output selection circuit 5124b as described above, a determination of whether the internal TDO signal output by the TAP controller is output to the connected die (STDO signal), or to an external JTAG interface (TDO signal) may be made.

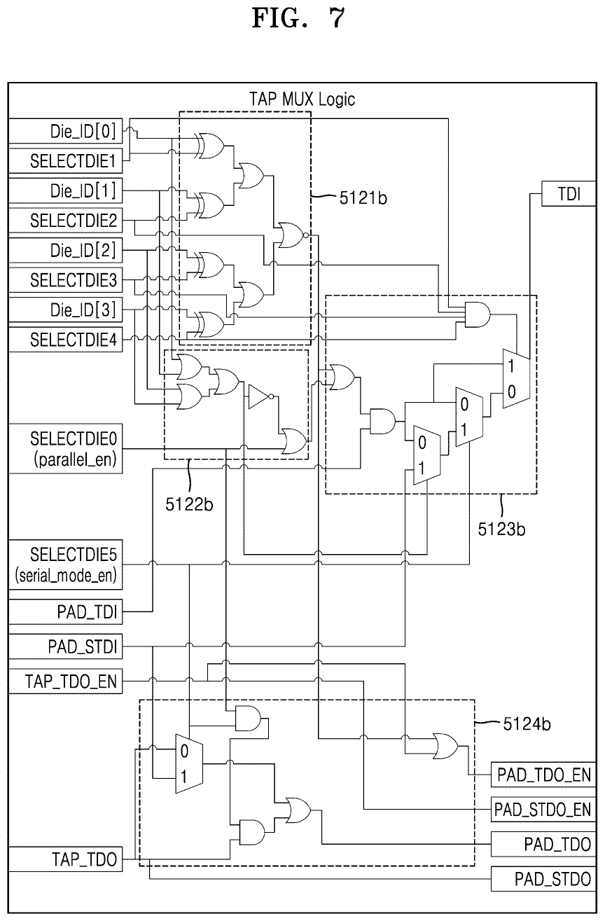

FIG. 7 illustrates a logic circuit of a TAP MUX circuit, according to one or more embodiments.

In the description of FIG. 7, duplicate descriptions of components given with reference to FIGS. 6A through 6C are omitted. Referring to FIG. 7, a logic circuit structure of a TAP MUX circuit is disclosed in which the logic selection circuit 5121b, the master/slave selection circuit 5122b, the input selection circuit 5123b, and the output selection circuit 5124b described with reference to FIGS. 6A through 6C are connected to each other.

By using the structure of this TAP MUX circuit, it may be possible to individually perform tests in series or in parallel on a multi-die package IC including a plurality of homogeneous dies. In this manner, weak points due to the limit of the number of package balls to be used in the test may be overcome to improve reliability of a package IC including a plurality of homogeneous dies, the number of test pins may be reduced, the test access time may be reduced, and thus performance of an IC may be improved.

Hereinafter, an operation method of the TAP MUX circuit in a plurality of test modes is briefly described.

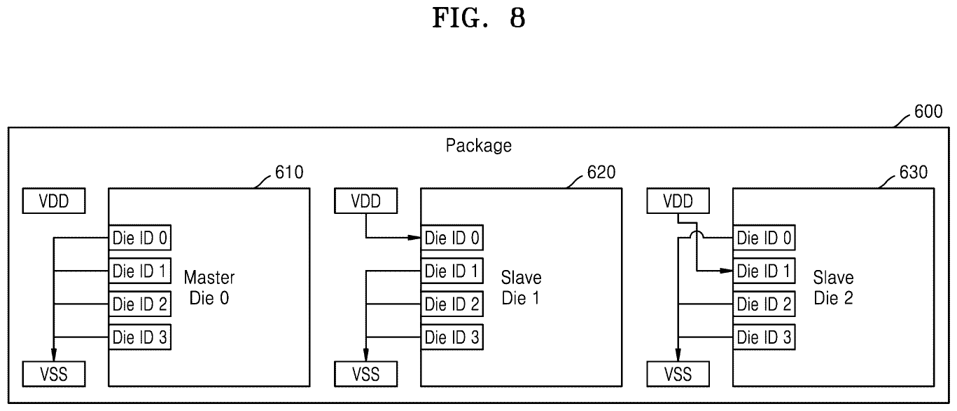

FIG. 8 is a diagram to describe a method of selecting a master die and slave dies, according to one or more embodiments.

FIG. 8 shows an example of setting the die ID, according to one or more embodiments. A package circuit 600 of FIG. 8 may include a first die 610, a second die 620, and a third die 630. Because the first die 610, the second die 620, and the third die 630 included in the package circuit 600 are homogeneous dies, an identification operation may be required to distinguish between the homogeneous dies. According to one or more embodiments, identification of each die may be determined by the die ID connected to a drain power supply (VDD) and a source power supply (VSS). In one or more embodiments, when all die IDs of the first die 610 are connected to the VSS, the first die 610 may be determined as a master die and the die ID may be set as 0000. In one or more embodiments, when there is a die ID connected to the VDD among the second die 620 and the third die 630, the die with the die ID may be determined as a slave die. However, this configuration is only an example of determining of the master die or the slave die, and the master die and slave die may also be determined in other ways.

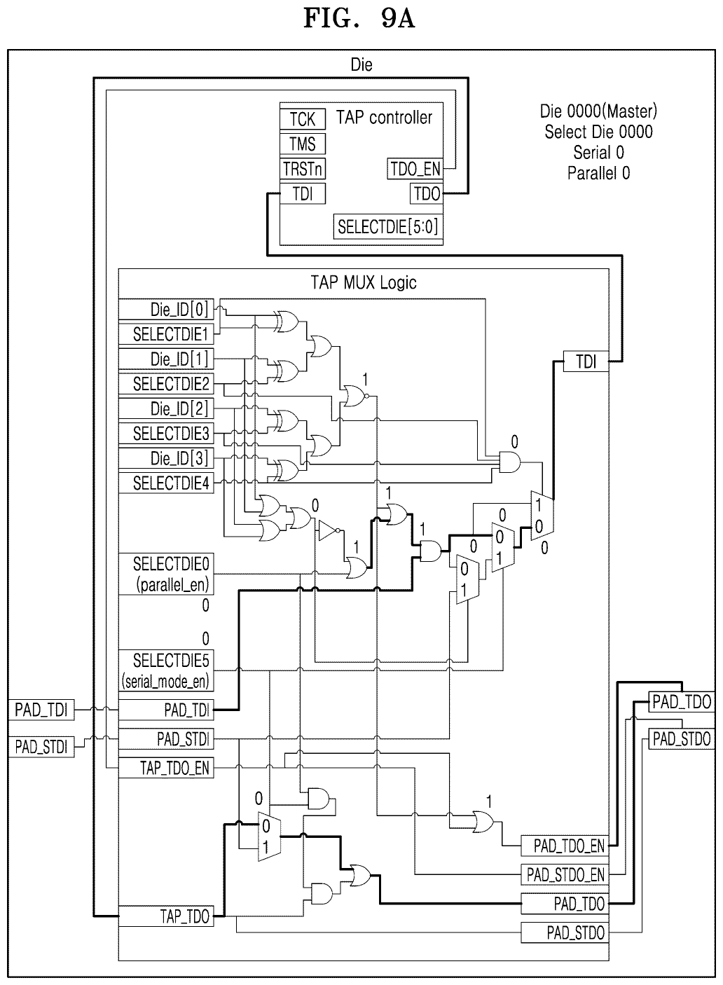

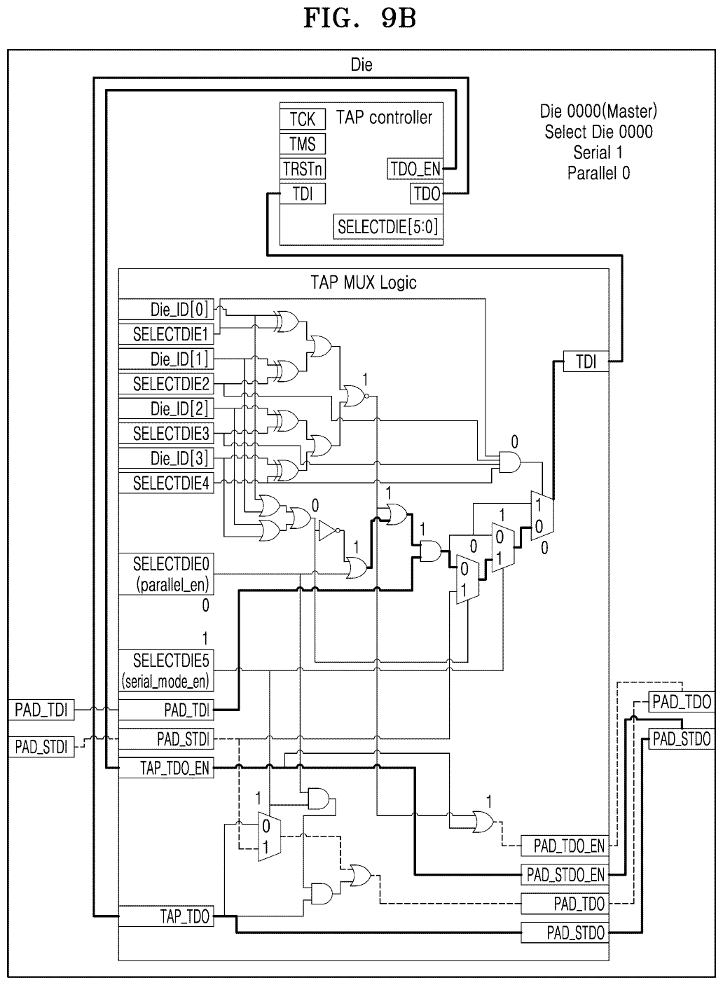

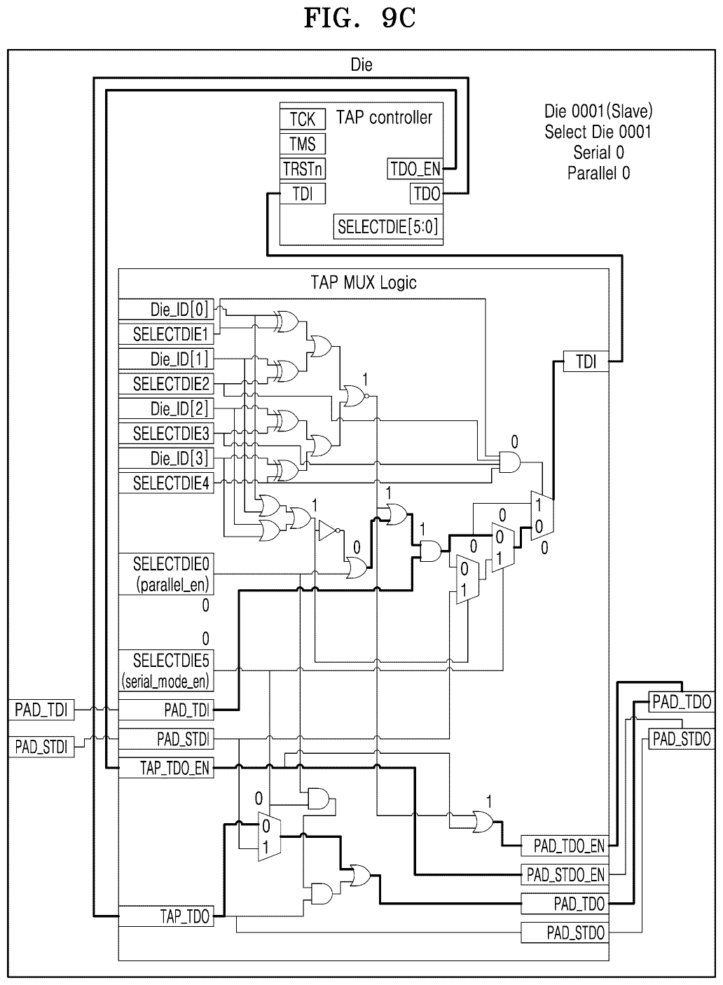

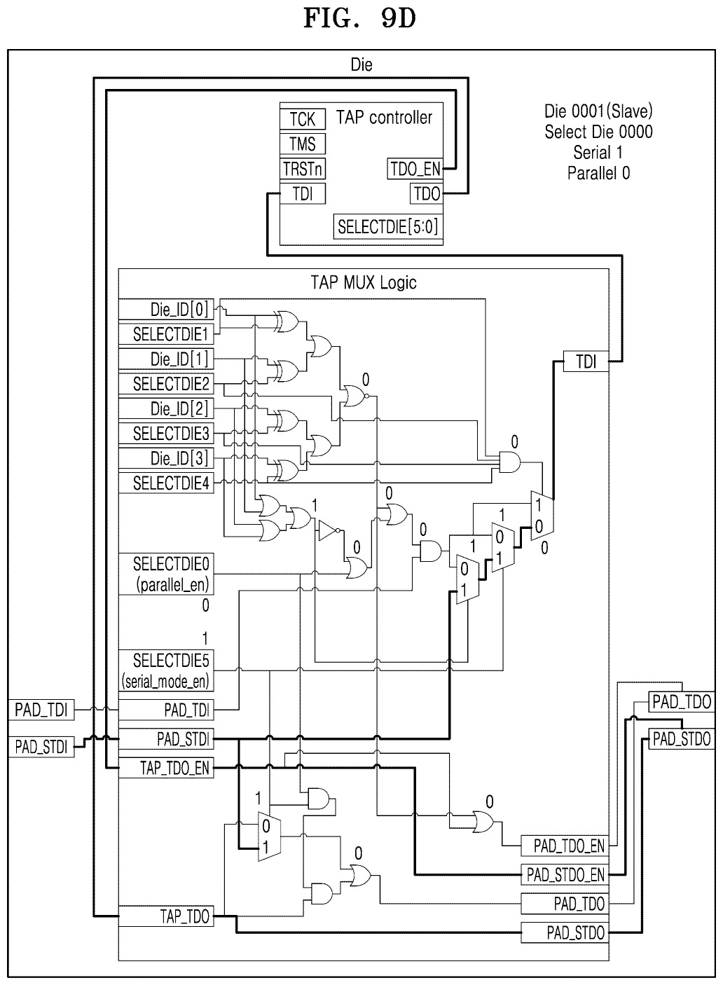

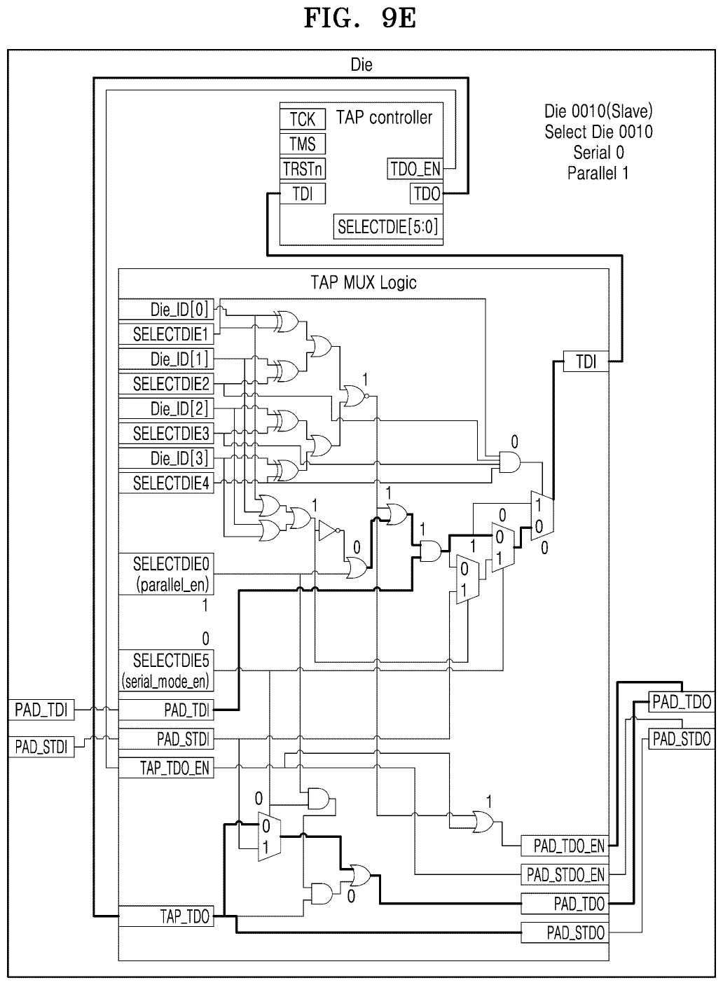

FIGS. 9A through 9E are diagrams of embodiments of selecting input signals and output signals in the test mode of a die. FIGS. 9A through 9E illustrate examples of setting the master/slave mode of individual dies and setting of the test mode in the JTAG interface according to the die ID, that is, the second selection signal, and a SELECTDIE, that is, the first selection signal. In FIGS. 9A through 9E, a number of 0 or 1 next to some logical devices may mean an output result of the corresponding logical devices under each condition. In FIGS. 9A through 9E, portions indicated by thick lines may indicate signal flows in respective modes.

The description of FIG. 9A is the case in which the die ID is 0000, that is, indicates a master die, the bit signal of the die ID included in a SELECT DIE signal, that is, the first selection signal, is 0000, and in a test mode signal, a serial test mode signal is 0 and a parallel test mode signal is 0. In other words, FIG. 9A illustrates a method of selecting an input/output of test data for the single test mode in a master die.

Referring to FIG. 9A, because the die ID matches the SELECTDIE signal, the output of the logic selection circuit may be 1, which may mean that the corresponding die is selected as a test target. In addition, because the SELECTDIE signal is 0000, the die may be determined as a master die in the master/slave selection circuit, and the output of the master/slave selection circuit may be 1.

Referring to FIG. 9A, because the die ID matches the SELECTDIE signal and accordingly, the corresponding die is selected as the test target, PAD_TDO_EN to be output from the corresponding die may be activated. In addition, as the serial test mode is not selected, a path of the STDO signal may be blocked. Accordingly, a PAD_TDI signal input from the outside of the package circuit may be selected and input as an internal TDI signal to drive the TAP controller, and as a result, a PAD_TDO may be as the output of the TAP controller to test individual dies.

The description of FIG. 9B is the case in which the die ID is 0000, that is, indicates a master die, the bit signal of the die ID included in a SELECT DIE signal, that is, the first selection signal, is 0000, and in a test mode signal, a serial test mode signal is 1 and a parallel test mode signal is 0. In other words, FIG. 9B discloses a method of selecting an input/output of test data for the serial test mode in a master die. In FIG. 9B, portions indicated by thick lines may indicate signal flows in a serial test mode in the master die, and portions indicated by dashed lines may indicate signal flows in the last die which is a serial test mode target.

Referring to FIG. 9B, outputs of the logic selection circuit and the

master/slave selection circuit may be the same as the outputs in FIG. 9A. When the serial test mode signal is applied as 1, the master die may drive the TAP controller by using the internal TDI signal input from the outside of the package circuit via the PAD_TDI, and the internal TDO signal, which is the output of the TAP controller, may be output as the PAD_STDO. In other words, this case may be configured in the form of a daisy-chain. Thereafter, the signal output to the PAD_STDO may be applied to the PAD_STDI of the next slave die. After the process, the TDO signal output by the last slave die may be applied to the STDI of the master die via the PAD_STDO, and may be output to PAD_TDO in the master die.

The description of FIG. 9C is a case in which the die ID is 0001 indicates a slave die, the SELECT DIE signal, that is, the signal of the die ID included in the first selection signal, is 0001, and in the test mode signal, the serial test mode signal is 0 and the parallel test mode signal is 0. In other words, FIG. 9C discloses a method of selecting an input/output of test data for the single test mode in a slave die.

As described above, because the die ID is 0001, the die may be determined as a slave die, and because the die ID matches the SELECT DIE signal, the corresponding die may be selected as a test target. In this case, the PAD_TDI signal input from the outside of the package circuit may operate the TAP controller, and may output test data via a PAT_TDO.

The description of FIG. 9D is a case in which the die ID of 0001 indicates a slave die, the SELECT DIE signal, that is, the signal of the die ID included in the first selection signal, is 0000, and in the test mode signal, the serial test mode signal is 1 and the parallel test mode signal is 0. In other words, FIG. 9D discloses a method of selecting an input/output of test data for the serial test mode in a slave die.

In this case, because the SELECT DIE signal is different from the die ID, the corresponding die may not be a die to be a test target, and may include a die which becomes a path in the serial test mode. In this case, the PAD_STDI may operate the TAP controller, and the TDO output by the TAP controller may be input to the STDI of the next die connected via the PAD_STDO.

The description of FIG. 9E is the case in which the die ID of 0010 indicates a slave die, the SELECT DIE signal, that is, the signal of the die ID included in the first selection signal, is 0010, and in the test mode signal, the serial test mode signal is 0 and the parallel test mode signal is 1. In other words, FIG. 9E discloses a method of selecting an input/output of test data for the parallel test mode in a slave die.

When entering the parallel test mode, the TDO of all dies except for the die subject to the parallel test mode may be blocked by a TDO_EN signal.

According to FIGS. 9A through 9E, an input signal and an output signal may be determined to be different, according to the master/slave modes and according to the serial/parallel/single test modes, and the STDI signal terminal and the STDO signal terminal capable of transmitting signals between individual dies may be used to test a die including a plurality of pins, that is, 5 pins, without additional interference with the IEEE 1149.1 standard. According to the disclosure, in a package circuit level test, because a parallel test on individual dies is possible, the test time may be improved. In addition, in a single package including homogeneous dies each with a minimum number of test pins in a package circuit operation, debugging of various modes may be performed with reduced complexity with a reduced number of test pins by providing in combination individual access to a single die, parallel access to a plurality of dies, and serial access of a daisy-chain structure. In addition, in this manner, the number of test pads may be reduced, which may act as an advantage in an arrangement of a microbump usable in a mission mode and accordingly, chip performance may be improved.

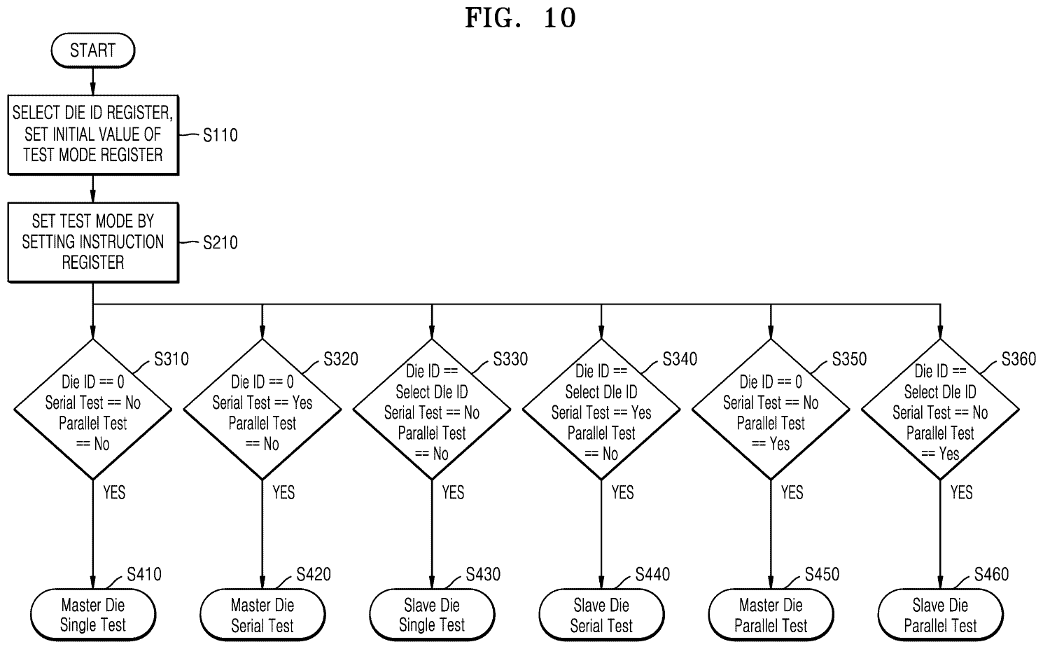

FIG. 10 is a flowchart of a test method of a package circuit, according to one or more embodiments.

Referring to operation S110, start values of a SELECT DIE ID register and a test mode register may be set. According to one or more embodiments, the set start values may include values set by the TAP controller. According to one or more embodiments, a start value of the first selection signal generated by the TAP controller may be set.

Referring to operation S210, the test mode may be set by using an IR setting. The test mode may be set by the TAP controller, and it may be possible to set which test mode to be determined. According to one or more embodiments, the test mode may be set to any one of the serial test mode, the parallel test mode, and the single test mode.

Referring to operation S310, a case in which the die ID is 0 and both a serial test signal and a parallel test signal are 0 is illustrated. In this case, because the die ID is 0, the corresponding die may be a master die, and because the mode is neither a serial mode nor a parallel mode, the mode may be the single test mode. Referring to operation S410, it may be identified that the mode is the single test mode of the master die.

Referring to operation S320, a case in which the die ID is 0, the serial test signal is 1, and the parallel test signal is 0 is illustrated. In this case, because the die ID is 0, the corresponding die may include a master die, and because the serial test signal is 1, the mode may be the serial test mode. Referring to operation S420, it may be identified that the mode is the serial test mode of the master die.

Referring to operation S330, a case in which the die ID matches the SELECT DIE IE, and both the serial test signal and the parallel test signal are 0 is illustrated. In this case, because the die ID is not 0, the die ID matches the SELECT DIE IE, and accordingly, the corresponding die represents a test target, the corresponding die may include a slave die, and because the mode is neither a serial mode nor a parallel mode, the mode may be the single test mode. Referring to operation S430, it may be identified that the mode is the single test mode of the slave die.

Referring to operation S340, a case in which the die ID matches the SELECT DIE IE, the serial test signal is 1, and the parallel test signal is 0 is illustrated. In this case, because the die ID is not 0, the die ID matches the SELECT DIE IE, and accordingly, the corresponding die represents a test target, the corresponding die may include a slave die, and because the serial test signal is 1, the mode may be the serial test mode. Referring to operation S440, it may be identified that the mode is the serial test mode of the slave die.

Referring to operation S350, a case in which the die ID is 0, the serial test signal is 0, and the parallel test signal is 1 is illustrated. In this case, because the die ID is 0, the corresponding die may include a master die, and because the parallel test signal is 1, the mode may be the parallel test mode. Referring to operation S450, it may be identified that the mode is the parallel test mode of the master die.

Referring to operation S360, a case in which the die ID matches the SELECT DIE IE, the serial test signal is 0, and the parallel test signal is 1 is illustrated. In this case, because the die ID is not 0, the die ID matches the SELECT DIE IE, and accordingly, the corresponding die represents a test target, the corresponding die may include a slave die, and because the parallel test signal is 1, the mode may be the parallel test mode. Referring to operation S460, it may be identified that the mode is the parallel test mode of the slave die.

When an identification of whether each die is a master die or a slave die, and when the test mode are determined, as described above, the input signal and the output signal may be determined by using the TAP controller and the TAP MUX circuit, and accordingly, the test of the homogeneous dies in various modes may be possible.

At least one of the components, elements, modules, circuits, units, or the like (collectively “components” in this paragraph) represented by a block or an equivalent indication (collectively “block”) in the above embodiments including the drawings, for example, the TAP controller, the TAP Mux Logic, and the various circuits described herein, or the like, may carry out the above-described function or functions. These blocks may be physically implemented by analog and/or digital circuits such as logic gates, integrated circuits, microprocessors, microcontrollers, memory circuits, passive electronic components, active electronic components, optical components, hardwired circuits and the like, and may optionally be driven by a firmware.

The various logic circuits discussed herein may, for example, be embodied in one or more semiconductor chips, or on substrate supports such as printed circuit boards and the like. While example of the logic circuits including digital logic elements have been provided, the circuits constituting a block may be implemented by dedicated hardware, or by a processor (e.g., one or more programmed microprocessors and associated circuitry), or by a combination of dedicated hardware to perform some functions of the block and a processor to perform other functions of the block. Each block of the embodiments may be physically separated into two or more interacting and discrete blocks without departing from the scope of the disclosure. Likewise, the blocks of the embodiments may be physically combined into more complex blocks without departing from the scope of the disclosure.

While the disclosure has been particularly shown and described with reference to embodiments thereof, it will be understood that various change in form and details may be made therein without departing from the spirit and scope of the following claims.

What is claimed is:

1. A package circuit comprising:
a plurality of homogeneous dies comprising a plurality of terminals; and
a joint test action group (JTAG) interface configured to transfer test signals applied to at least one of the plurality of homogeneous dies,
wherein a test mode of the plurality of homogeneous dies comprises at least one of:
a first mode configured to test in series at least two dies among the plurality of homogeneous dies;
a second mode configured to test in parallel at least two dies among the plurality of homogeneous dies; and
a third mode configured to test individually any one die among the plurality of homogeneous dies, and
wherein the JTAG interface comprises four or five signal terminals.

2. The package circuit of claim 1, wherein each of the plurality of homogeneous dies comprises:
a tap controller configured to select the test mode; and
a tap multiplexer (mux) circuit configured to determine an input signal and an output signal according to the test mode.

3. The package circuit of claim 2, wherein for each of the plurality of homogeneous dies, the tap controller is further configured to transmit, to the tap mux circuit, a first selection signal comprising information configured to select the test mode and information configured to distinguish between the plurality of homogeneous dies.

4. The package circuit of claim 3, wherein for each of the plurality of homogeneous dies, the tap mux circuit is further configured to:
receive the first selection signal,
receive a second selection signal comprising information for distinguishing the plurality of homogeneous dies,
determine whether a corresponding die among the plurality of homogeneous dies is to be tested based on at least one of the first selection signal and the second selection signal, and
determine whether the corresponding die among the plurality of homogeneous dies is a master die or a slave die based on at least one of the first selection signal and the second selection signal.

5. The package circuit of claim 4, wherein the tap mux circuit is further configured to determine the input signal according to whether the corresponding die is to be tested and whether the corresponding die is the master die or the slave die.

6. The package circuit of claim 4, wherein the tap mux circuit is further configured to determine the output signal according to whether the corresponding die is to be tested, and whether the corresponding die is the master die or the slave die.

7. The package circuit of claim 2, wherein the tap mux circuit comprises:
a logic selection circuit configured to determine whether a die including the tap mux circuit, among the plurality of homogeneous dies, is a test target; and
a master/slave selection circuit configured to determine whether the die including the tap mux circuit, among the plurality of homogeneous dies, is a master die or a slave die.

8. The package circuit of claim 7, wherein the tap mux circuit is further configured to determine an input signal applied to the tap controller based on an output of the logic selection circuit and an output of the master/slave selection circuit.

9. The package circuit of claim 7, wherein the tap mux circuit is further configured to determine a direction of the output signal to be finally output based on an output of the logic selection circuit and an output of the master/slave selection circuit.

10. A package circuit comprising:
a first die comprising a plurality of first terminals;
a second die comprising a plurality of second terminals; and
a joint test action group (JTAG) interface configured to transfer test signals applied to at least one of the first die or the second die,
wherein the first die and the second die comprise homogeneous dies,
wherein a number of terminals included in the JTAG interface is four or five, and
wherein the plurality of first terminals and the plurality of second terminals each comprises:
signal terminals corresponding to the terminals included in the JTAG interface; and
a first signal terminal configured to receive identification (ID) information of a die for distinguishing the first die from the second die.

11. The package circuit of claim 10, wherein the plurality of first terminals further comprises:
a standard input (STDI) signal terminal configured to connect to an output of the second die; and
a standard output (STDO) signal terminal configured to connect to an input of the second die.

12. The package circuit of claim 10, wherein a number of the plurality of first terminals is identical to a number of the plurality of second terminals.

13. The package circuit of claim 10, wherein the first signal terminal is configured to receive signals from outside of the first die and the second die.

14. The package circuit of claim 13, wherein each of the plurality of first terminals and the plurality of second terminals further comprises a second signal terminal for inputting or outputting signals comprising the ID information generated inside the first die and the second die.

15. The package circuit of claim 14, wherein the second signal terminal is configured to receive a signal comprising information about test modes of the first die and the second die.

16. The package circuit of claim 15, wherein the test mode comprises:
a first mode configured to test the first die and the second die in series;
a second mode configured to test the first die and the second die in parallel; and
a third mode configured to test the first die or the second die individually.

17. A package circuit comprising:
a plurality of homogeneous dies comprising a plurality of terminals; and
a joint test action group (JTAG) interface configured to transfer test signals applied to at least one of the plurality of homogeneous dies,
wherein the JTAG interface comprises a test clock (TCK) signal terminal, a test mode select (TMS) signal terminal, a test reset (TRST) signal terminal, a test data input (TDI) signal terminal, and a test data output (TDO) signal terminal, and
wherein each of the plurality of homogeneous dies comprises:
signal terminals respectively corresponding to the TCK signal terminal, the TMS signal terminal, the TRST signal terminal, the TDI signal terminal, and the TDO signal terminal; and
standard input (STDI) signal terminals and standard output (STDO) signal terminals configured to transfer input signals and output signals between the plurality of homogeneous dies.

18. The package circuit of claim 17, wherein each of the plurality of homogeneous dies comprises a second signal terminal configured to receive information about a test mode generated inside the plurality of homogeneous dies and information about a corresponding die identification (ID).

19. The package circuit of claim 18, wherein each of the plurality of homogeneous dies comprises a first signal terminal configured to receive, from outside of the plurality of homogeneous dies, hard-coded information for distinguishing between die IDs of each of the plurality of homogeneous dies.

20. The package circuit of claim 19, wherein each of the plurality of homogeneous dies is configured to determine, based on a signal input to the first signal terminal and a signal input to the second signal terminal, whether the plurality of homogeneous dies are test targets, to determine whether a mode is a test mode, and to determine whether the plurality of homogeneous dies are a master die or a slave die.
